(19) United States
(12) Patent Application Publication
(10) Pub. No.: US 2007/0218684 A1
(43) Pub. Date: Sep. 20, 2007

(54) Method for fabricating storage node contact plug of semiconductor device

(75) Inventor: Jong-Sik Kim, Kyoungki-do (KR)

Correspondence Address: MAYER, BROWN, ROWE & MAW LLP, 1909 K STREET, N.W., WASHINGTON, DC, 20006, US

(73) Assignee: HYNIX Semiconductor Inc.

(21) Appl. No.: 11/643,915

(22) Filed: Dec. 22, 2006

(30) Foreign Application Priority Data
Mar. 14, 2006 (KR) 10-2006-0023549
Nov. 29, 2006 (KR) 10-2006-0119207

(51) Int. Cl. H01L 21/44

(52) U.S. Cl. 438/652; 438/675; 438/703

(57) ABSTRACT

A method for fabricating a storage node contact plug of a semiconductor device includes forming an insulation layer over a substrate, etching the insulation layer to form a contact hole, forming a first conductive layer to fill the contact hole, the first conductive layer including a void, etching the first conductive layer to expose the void, forming a second conductive layer to fill the exposed void, and forming a third conductive layer over the second conductive layer.

### CROSS-REFERENCES TO RELATED APPLICATIONS

The present invention claims priority of Korean patent application number 10-2006-0023549 and 10-2006-0119207, filed on Mar. 14, 2006 and Nov. 29, 2006, which are incorporated by reference in their entirety.

### BACKGROUND OF THE INVENTION

The present invention relates to a method for fabricating a semiconductor device; and more particularly, to a method for fabricating a storage node contact plug of a semiconductor device.

As the scale of a dynamic random access memory (DRAM) device has been highly integrated, a design rule of the device has been continuously reduced and an operation of the device with a high speed has been required. As a result, a contact area of the device is also decreased and accordingly, a resistance level of the device is increased. Recently, there has been an effort to reduce resistance of a contact.

FIG. 1 is a cross-sectional view illustrating a typical storage node contact plug of a semiconductor device. A first insulation layer 12 is formed over a substrate 11 and then, a plurality of landing plugs 13 are filled into a plurality of contact holes formed inside the first insulation layer 12. A second insulation layer 14 is formed over the landing plugs 13 and the first insulation layer 12. A plurality of storage node contact holes 15 exposing surfaces of the landing plugs 13 are formed in the second insulation layer 14. A plurality of storage node contact plugs 16 fill the storage node contact holes 15.

However, when a polysilicon layer used as the storage node contact plugs 16 is filled, heights of the storage node contact holes 16 become greater, thereby increasing an aspect ratio. Accordingly, a step coverage property of the polysilicon layer may be degraded and voids denoted with a reference letter V may be generated inside the storage node contact plugs 16.

The voids V may act as a main factor to increase a resistance level of a contact. Also, since the polysilicon layer itself has a high resistance level, reliability and yields of the device may be degraded.

The voids V may be generated during filling various contact plugs into the contact holes having a high aspect ratio. For instance, when filling a landing plug, a bit line contact plug and a metal contact plug known as M1C, the voids V may be produced.

### SUMMARY OF THE INVENTION

A specific embodiment of the present invention is directed to provide a method for fabricating a storage node contact plug of a semiconductor device capable of preventing voids from being produced inside the storage node contact plug and reducing a resistance level of the storage node contact plug itself.

In accordance with one aspect of the present invention, there is provided a method for fabricating a storage node contact plug of a semiconductor device, including: forming an insulation layer over a substrate; etching the insulation layer to form a contact hole; forming a first conductive layer to fill the contact hole, the first conductive layer including a void; etching the first conductive layer to expose the void; forming a second conductive layer to fill the exposed void; and forming a third conductive layer over the second conductive layer.

### BRIEF DESCRIPTION OF THE DRAWINGS

FIG. 1 is a cross-sectional view illustrating a typical storage node contact plug of a semiconductor device.

FIGS. 2A to 2F are cross-sectional views illustrating a method for fabricating a semiconductor device in accordance with an embodiment of the present invention.

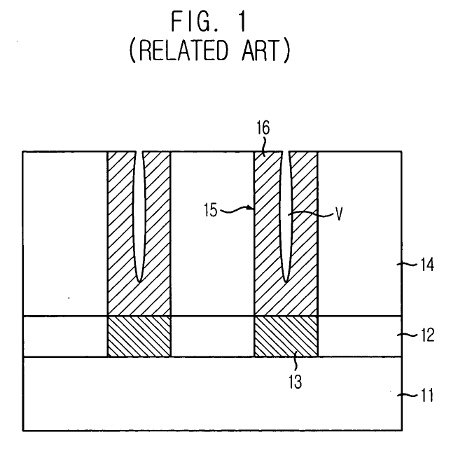

### DESCRIPTION OF SPECIFIC EMBODIMENTS

According to one embodiment of the present invention, a contact plug includes first to third conductive layers to reduce voids that can be produced when filling the conductive layers into a contact hole having a high aspect ratio. Particularly, resistivity of the second and third conductive layers is smaller than that of the first conductive layer. Accordingly, it is possible to reduce a resistance level of the storage node contact plug itself.

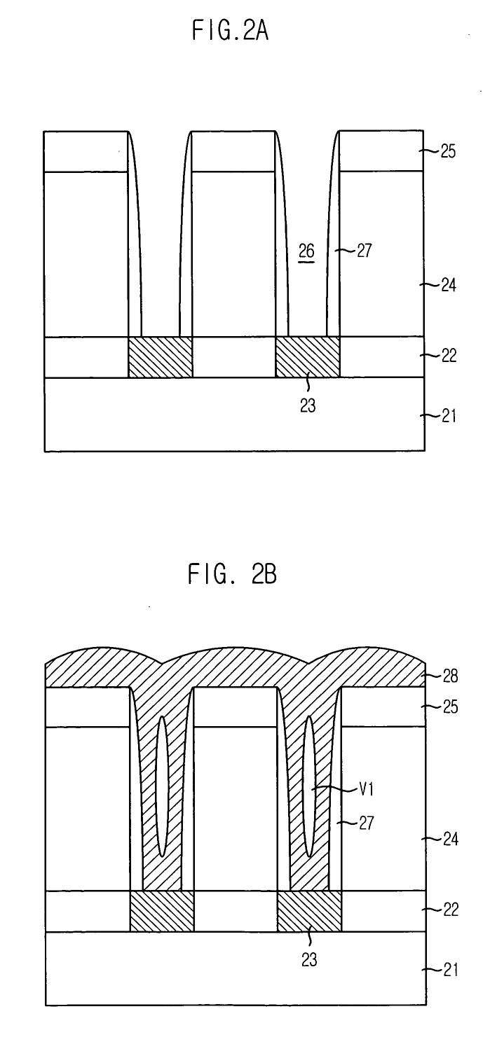

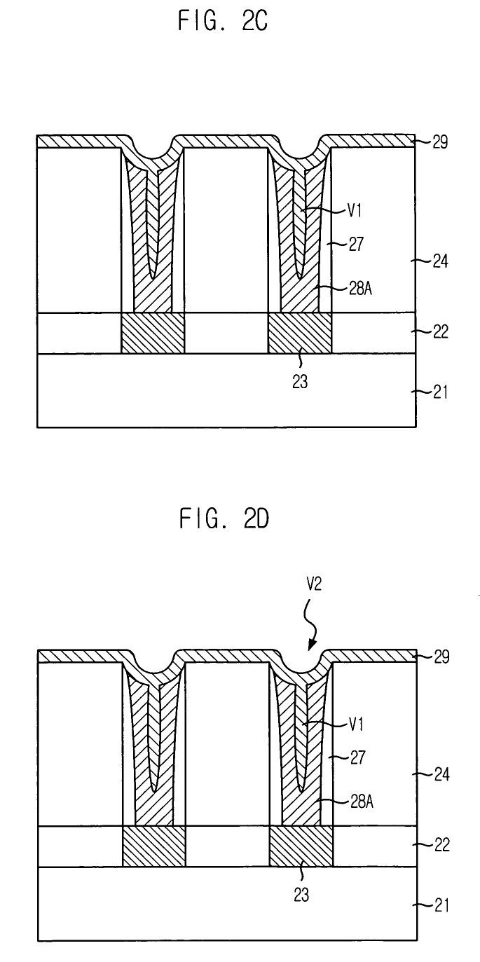

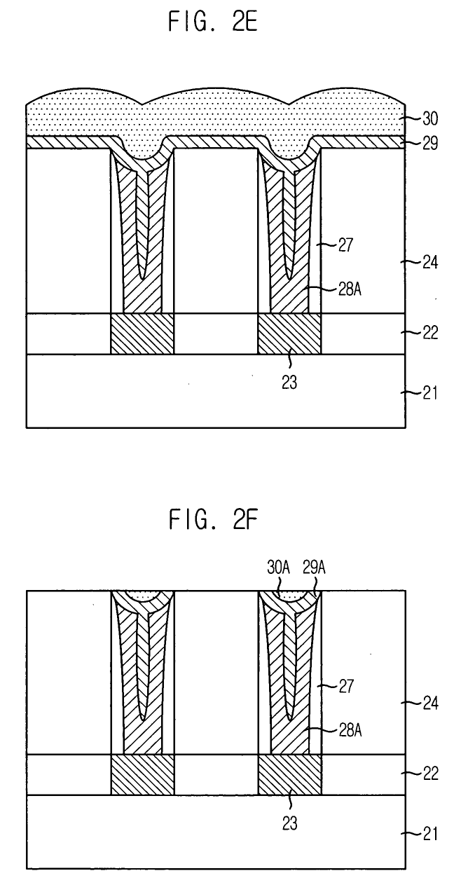

FIGS. 2A to 2F are cross-sectional views illustrating a method for fabricating a storage node contact plug in accordance with an embodiment of the present invention. As shown in FIG. 2A, a plurality of landing plugs 23 are formed over a substrate 21. In more details of the formation of the landing plugs 23, a first insulation layer 22 is formed over the substrate 21 and then, the first insulation layer 22 is etched to form a plurality of contact holes. A polysilicon layer is formed inside the contact holes and an etch back process is performed to obtain the landing plugs 23.

The first insulation layer 22 is formed performing one selected from a group consisting of a chemical vapor deposition (CVD) method, a physical vapor deposition (PVD) method, and an atomic layer deposition (ALD) method. Before the landing plugs 23 are formed, processes required to form a dynamic random access memory (DRAM) device including a device isolation process, a transistor formation process, and a word line formation process are performed.

A second insulation layer 24 is formed over the first insulation layer 22. The second insulation layer 24 is formed performing one selected from a group consisting of a CVD method, a PVD method, and an ALD method. A bit line can be formed before the second insulation layer 24 is formed.

A hard mask pattern 25 is formed over the second insulation layer 24. In more details of the formation of the hard mask pattern 25, a polysilicon layer used to form the hard mask pattern 25 is formed over the second insulation layer 24 and then, etched using a photoresist pattern (not shown) to obtain the hard mask pattern 25. The photoresist pattern can be referred to as a storage node contact mask, and the hard mask pattern 25 is formed to supplement insufficient selectivity of the photoresist pattern.

The second insulation layer 24 is etched using the hard mask pattern 25 as an etch barrier to form a plurality of storage node contact holes 26 exposing surfaces of the landing plugs 23.

A spacer insulation layer is formed and then, an etch back process is performed to form a plurality of storage node contact spacers 37 contacting sidewalls of the storage node contact holes 26. The storage node contact spacers 37 are formed to reduce an electric short circuit between a subsequent storage node contact plug and the bit line (not shown). The storage node contact spacers 37 include a nitride-based layer. Particularly, a silicon nitride layer is formed to a thickness ranging from approximately 1 Å to approximately 2,000 Å and then, subjected to an etch back process to obtain the storage node contact spacers 37. The silicon nitride layer has a structure of SiₓN_{y}, wherein x ranges from approximately 1 to approximately 5, and y ranges from approximately 1 to approximately 7.

A dip process using a wet chemical can be additionally performed to remove a parasitic oxide layer formed over the surfaces of the landing plugs 23. The dip process using the wet chemical can be performed using one selected from a group consisting of a solution of hydrogen fluoride (HF), a solution of buffered oxide etchant (BOE) formed by mixing HF₄ and NH₄F, a mixture solution of hydrogen peroxide (H₂O₂) and water (H₂O).

As shown in FIG. 2B, a first conductive layer 28 is formed over an entire surface of the resulting structure to form a plurality of storage node contact plugs by filling the storage node contact holes 26 (see FIG. 2A). The first conductive layer 28 includes a polysilicon layer. The polysilicon layer is formed to a thickness ranging from approximately 10 Å to approximately 5,000 Å at a temperature ranging from approximately 200° C. to approximately 1,000° C. Also, one selected from a group consisting of a CVD method, a PVD method, and an ALD method can be used to form the polysilicon layer.

During forming the first conductive layer 28, a step coverage property can be degraded due to a high aspect ratio of the storage node contact holes 26 and accordingly, first voids V1 can be produced inside the storage node contact holes 26 (see FIG. 2A).

The first voids V1 can be prevented by performing the following processes which will be explained hereinafter. As shown in FIG. 2C, the first conductive layer 28 is planarized performing a planarization process to expose the second insulation layer 24 that has been etched, i.e., to expose at least the first voids V1. As a result, the planarized first conductive layer 28A exists only inside the storage node contact holes 26 (see FIG. 2A). The planarization process can be performed using one of an etch back process and a chemical mechanical polishing (CMP) process. Through performing the planarization process, the first voids V1 inside the planarized first conductive layer 28A can be exposed.

As shown in FIG. 2D, a second conductive layer 29 is formed to fill the first voids V1 generated inside the planarized first conductive layer 28A. The second conductive layer 29 includes a titanium nitride (TiN) layer. The TiN layer has resistivity lower than that of the polysilicon layer used as the first conductive layer 28.

Due to the formation of the second conductive layer 29, the first voids V1 existing inside the planarized first conductive layer 28A can be filled. However, second voids V2 are also generated after the second conductive layer 29 is formed.

As shown in FIG. 2E, a third conductive layer 30 is formed over the second conductive layer 29 to fill the second voids V2 generated even after the second conductive layer 29 is formed. The third conductive layer 30 includes a tungsten layer having resistivity lower than that of the polysilicon layer used as the first conductive layer 28.

The second conductive layer 29 and the third conductive layer 30 are formed to a thickness ranging from approximately 10 Å to approximately 5,000 Å at a temperature ranging from approximately 200° C. to approximately 1,000° C., respectively. Also, one selected from a group consisting of a CVD method, a PVD method, and an ALD method is used to form the second conductive layer 29, and the third conductive layer 30.

As shown in FIG. 2F, an etch back process is performed to etch the third conductive layer 30, and the second conductive layer 29 in manner to expose the surface of the second insulation layer 24 that has been etched. As a result, the patterned third conductive layer 30A and the patterned second conductive layer 29A are obtained. A plurality of storage node contact plugs, each with a triple structure of the patterned third conductive layer 30A, the patterned second conductive layer 29A, and the planarized first conductive layer 28A, are formed.

Each of the storage node contact plugs is formed with the triple structure of the planarized first conductive layer 28A including the polysilicon layer, the patterned second conductive layer 29A including the TiN layer, and the patterned third conductive layer 30A including the tungsten layer. The TiN layer is formed over the polysilicon layer to remove the voids inside the polysilicon layer and then, the tungsten layer is formed over the TiN layer to remove the voids inside the TiN layer. Also, since the TiN layer and the tungsten layer, both having resistivity lower than the polysilicon layer, are formed, a resistance level of the storage node contact plugs themselves can be reduced.

Accordingly, since the TiN layer and the tungsten layer have the resistivity lower than that of the polysilicon layer, the storage node contact plugs including the TiN layer and the tungsten layer can more reduce a resistance level than the typical storage node contact plug including only the polysilicon layer. As a result, reliability of the device and yields of the products can be increased.

According to this embodiment of the present invention, the step coverage property of the polysilicon layer used as the conductive layer to form the storage node contact plugs is degraded due to an increased aspect ratio. Thus, the voids can be generated inside the storage node contact plugs, thereby degrading the device property. However, the storage node contact plugs are embodied forming the TiN layer over the polysilicon layer to remove the void, and the tungsten layer to reduce a resistance level. Thus, the voids can be removed and contact resistance can be decreased.

The present invention can be applied to a method for forming other kinds of contact plugs filled into a contact hole having a high aspect ratio in addition to the storage node contact plugs. The above mentioned contact plugs include a landing plug, a bit line contact plug, and a metal contact plug referred to as a M1C, and can be applied when filing a contact hole for the landing plug having a high aspect ratio, a contact hole for the bit line contact plug, and a contact hole for the metal contact plug.

According to this embodiment of the present invention, the polysilicon layer is formed and then, the TiN layer formed thereon. Thereafter, the tungsten layer is formed over the TiN layer to form the storage node contact plugs. Accordingly, the voids generated due to the poor step coverage property can be reduced, and electrons, (e.g., current) can smoothly flow due to the formation of the tungsten layer having resistivity lower than that of the typical polysilicon layer during the device operation.

As a result, the semiconductor device can operate with a high speed, thereby improving reliability of the DRAM device. A failure of the storage node contact plugs and a contact resistance can be reduced. The yields of the products can be increased as well.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a storage node contact plug of a semiconductor device, comprising:
forming an insulation layer over a substrate;
etching the insulation layer to form a contact hole;
forming a first conductive layer to fill the contact hole, first conductive layer including a void;
etching the first conductive layer to expose the void;
forming a second conductive layer to fill the exposed void; and
forming a third conductive layer over the second conductive layer.

2. The method of claim 1, wherein the second conductive layer is formed to a thickness sufficient to fill the void produced inside the first conductive layer filling the contact hole.

3. The method of claim 1, wherein the etching of the first conductive layer to expose the void produced inside the first conductive layer comprises performing an etch back process.

4. The method of claim 3, wherein the second conductive layer and the third conductive layer include a conductive material having resistivity lower than that of the first conductive layer.

5. The method of claim 4, wherein the first conductive layer includes a polysilicon layer, the second conductive layer includes a titanium nitride (TiN) layer, and the third conductive layer includes a tungsten layer.

6. The method of claim 5, wherein the first, second and third conductive layers are formed at a temperature ranging from approximately 200° C. to approximately 1,000° C.

7. The method of claim 5, wherein the first, second and third conductive layers are formed to a thickness ranging from approximately 10 Å to approximately 5,000 Å.

8. The method of claim 5, wherein the first, second and third conductive layers are formed performing one selected from a group consisting of a chemical vapor deposition (CVD) method, a physical vapor deposition (PVD) method, and an atomic layer deposition (ALD) method.

9. The method of claim 1, before the forming of the first conductive layer, further comprising:
forming a plurality of spacers over sidewalls of the contact hole; and
cleaning the contact hole.

10. The method of claim 9, wherein the spacers include a nitride-based material.

11. The method of claim 9, wherein the cleaning of the contact hole comprises performing a dip process using a wet chemical.

12. The method of claim 11, wherein the dip process using the wet chemical comprises using a solution of hydrogen fluoride (HF), a solution of buffered oxide etchant (BOE), and a mixture solution of hydrogen peroxide (H₂O₂) and water (H₂O).

13. The method of claim 1, wherein the contact hole is one selected from a group consisting of a contact hole where a storage node contact plug fills, a contact hole where a landing plug fills, a contact hole where a bit line contact fills, and a contact hole where a metal contact plug fills.
